(19) United States
(12) Patent Application Publication
(10) Pub. No.: US 2024/0186205 A1
(43) Pub. Date: Jun. 6, 2024

(54) PACKAGE STRUCTURE AND PACKAGING METHOD

(71) Applicant: Richtek Technology Corporation, Hsinchu (TW)

(72) Inventors: Min-Shun LO, Hsinchu (TW); Shih-Chieh LIN, Hsinchu (TW)

(21) Appl. No.: 18/328,786

(22) Filed: Jun. 5, 2023

(30) Foreign Application Priority Data
Dec. 5, 2022 (TW) 111146524

(51) Int. Cl. H01L 23/367; H01L 21/56; H01L 23/00; H01L 23/31; H01L 23/495

(52) U.S. Cl. CPC H01L 23/367; H01L 21/561; H01L 23/3107; H01L 23/49503; H01L 24/32; H01L 24/48; H01L 24/73; H01L 24/83; H01L 24/96; H01L 2224/32245; H01L 2224/48245; H01L 2224/73215; H01L 2224/838; H01L 2224/96

(57) ABSTRACT

A package structure, includes: a lead frame, having a die pad and lead pads around the die pad; a chip die on the die pad, wherein the lead pads are electrically connected with the chip die via lead wires; a thermal conductive adhesive layer on the chip die; a thermal conductive plate on the thermal conductive adhesive layer; and a packaging material, encapsulating the lead frame, the chip die, the thermal conductive plate, and the thermal conductive adhesive layer. The thermal conductive plate is exposed on a top of the package material, and the lead frame is exposed on a bottom surface of the package material. The package structure has an upper thermal conduction path passing through the chip die, the thermal conductive adhesive layer, and the thermal conductive plate; and a lower thermal conduction path passing through the chip die and the lead frame.

### CROSS REFERENCE

The present invention claims priority to TW 111146524 filed on Dec. 5, 2022.

### BACKGROUND OF THE INVENTION

### Field of Invention

The present invention relates to a package structure, especially to a package structure having a thermal conductive adhesive layer and a thermal conductive plate for increasing its thermal conductivity.

### Description of Related Art

As shown in FIG. 1, a prior package structure 10 conducts heat from a chip die 14 via a heat dissipation cover 16, to a top surface of the package structure 10. The heat dissipation cover 16 is required to contact the lead frame 12 and cover the chip die 14, so its shape is complicated in order to fit these needs; as thus, it does not have flexibility to be applied to various different package structures (for example, different package structures packaging different sizes of chip dies). Therefore, the related package production cost becomes high. Besides, for the heat inside the chip die 14 to dissipate, the heat needs to pass from the top of the chip die 14 through a package material 18 to the heat dissipation cover 16, but the thermal resistance of the package material 18 is generally higher than the heat dissipation cover 16, so the heat dissipation effect is quite limited, although the heat dissipation cover 16 is provided. In summary, the cost and effect of the prior art package structure 10 are not satisfactory.

To solve the problems of the prior art, the present invention provides an innovated package structure, to significantly increase the thermal dissipation effect through a package structure produced by a simple manufacturing process.

### SUMMARY OF THE INVENTION

In one perspective, the present invention provides a package structure, which comprises: a lead frame, including a die pad and a plurality of lead pads around the die pad; a chip die, disposed on the die pad, wherein the lead pads are electrically connected with the chip die via a plurality of lead wires, respectively; a thermal conductive adhesive layer, disposed on the chip die at a same elevation level as a part of the lead wires above the chip die; a thermal conductive plate, disposed on the thermal conductive adhesive layer; and a packaging material, encapsulating the lead frame, the chip die, the thermal conductive adhesive layer, and the thermal conductive plate, wherein the thermal conductive plate is exposed on a top surface of the package material, and the lead frame is exposed on a bottom surface of the package material;
wherein the package structure includes an upper thermal conduction path and a lower thermal conduction path, the upper thermal conduction path passing through the chip die, the thermal conductive adhesive layer, and the thermal conductive plate, and the lower thermal path passing through the chip die and the lead frame.

In one embodiment, the thermal conductive plate does not contact the lead frame.

In one embodiment, a part of the lead wires above the chip die are buried in the thermal conductive adhesive layer; or, a part of the lead wires above the chip die are disposed outside the thermal conductive adhesive layer.

In one embodiment, the lead frame, the chip die, the thermal conductive adhesive layer, and the thermal conductive plate are respectively disposed at different elevation levels.

In one embodiment, in a manufacturing process of the package structure, the thermal conductive plates are disposed on a tape by the thermal conductive adhesive layer, whereafter each set of the thermal conductive plate and the thermal conductive adhesive layer is removed from the tape, to be disposed on the corresponding chip die.

In one embodiment, the package structure of the present invention can be applied to a packages of quad flat no lead (QFN), quad flat package (QFP), ball grid array (BGA), land grid array (LGA), or dual flat no lead (DFN).

In one embodiment, an exposed portion of the thermal conductive plate on the package material, includes a shape of square, rectangular, circle, oval, triangular, or polygonal.

In one perspective, the present invention provides a packaging method, which comprises: providing a tape, which includes plural sets of thermal conductive adhesive layers and thermal conductive plates thereon; removing each set of the thermal conductive adhesive layer and thermal conductive plate from the tape; providing a plurality of lead frames connected to each other, each of the lead frames including a die pad and a plurality of lead pads, wherein a chip die is disposed on the die pad, and a plurality of lead wires are disposed between the chip die and the lead pads; disposing each set of the thermal conductive adhesive layer and the thermal conductive plate on a corresponding one of the chip dies; providing a package material to encapsulate the lead frames, the chip dies, the thermal conductive adhesive layers, and the thermal conductive plates, to form a continuous pre-cutting package structure, wherein a top surface of the thermal conductive plate is exposed on a top surface of the continuous pre-cutting package structure, and a bottom surface of the lead frames is exposed on a bottom surface of the continuous pre-cutting package structure; and dividing the continuous package structure into a plurality of package structures; wherein each of the package structures includes an upper thermal conduction path and a lower thermal conduction path, the upper thermal conduction path passing through the chip die, the thermal conductive adhesive layer, and the thermal conductive plate, the lower thermal path passing through the chip die and the lead frame.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a prior art package structure.

FIG. 2 shows a schematic diagram of a package structure according to one embodiment of the present invention.

FIG. 3 shows a schematic diagram of a package structure according to another embodiment of the present invention.

FIG. 4 shows a schematic diagram of a package structure according to another embodiment of the present invention.

FIGS. 5A-5G show steps of a packaging method according to one embodiment of the present invention.

FIG. 6 shows various shapes of exposed portions on top surfaces of the package structures according to several embodiments of the present invention.

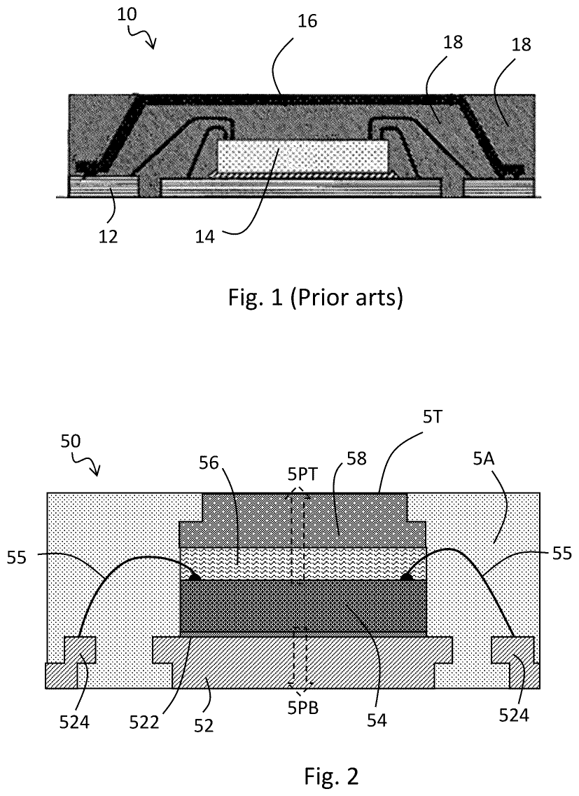

### DESCRIPTION OF THE PREFERRED EMBODIMENTS

The drawings as referred to throughout the description of the present invention are for illustration only, to show the interrelations between the components or units, but not drawn according to actual scale of sizes.

FIGS. 2, 3, and 4, respectively show package structures 50, 60, and 70 according to several embodiments of the present invention. Each of the package structures 50, 60, and 70, includes: a lead frame 52, a chip die 54, a thermal conductive adhesive layer 56, a thermal conductive plate 58, and a packaging material 5A. The lead frame 52 includes a die pad 522 and plural lead pads 524 around the die pad 522. The chip die 54 is disposed on the die pad 522, wherein the lead pads 524 are electrically connected with the chip die 54 via plural lead wires 55, for transmitting signals between the lead pads 524 and the chip die 54. The thermal conductive adhesive layer 56 is disposed on the chip die 54 at the same elevation level as a part of the lead wires above the chip die 54. The thermal conductive plate 58 is disposed on the thermal conductive adhesive layer 56, wherein the thermal conductive plate 58 is made of a high thermal conductive material, and the thermal conductive adhesive layer 56 adheres the thermal conductive plate 58 onto the chip die 54. The packaging material 5A encapsulates the lead frame 52, the chip die 54, the thermal conductive adhesive layer 56, and the thermal conductive plate 58, so that the package structure 50, 60, or 70 becomes an integrated structure, wherein a top surface of the thermal conductive plate 58 is exposed on a top surface 5T of the package material, and a bottom surface of the lead frame 52 is exposed on a bottom surface of the package material. The package structure 50, 60, or 70 includes an upper thermal conduction path 5PT and a lower thermal conduction path 5PB, to transmit the heat generated from the chip die 54 to the outside of the package structure 50, 60, or 70. The upper thermal conduction path 5PT passes through the chip die 54, the thermal conductive adhesive layer 56, and the thermal conductive plate 58. The lower thermal conduction path 5PB passes through the chip die 54 and the lead frame 52. The thermal dissipation efficiency of the chip die 54 is greatly improved in comparison with the prior art because of the upper thermal conduction path 5PT and the lower thermal conduction path 5PB.

In one embodiment, the thermal conductive plate 58 is made of s high thermal conductive material, for transferring the heat from the chip die 54 to the thermal conductive plate 58. The high thermal conductive material for example includes one or more of the following materials: metal (such as copper, aluminum, etc.), composite materials having high thermal conductivity, electroplating materials with (such as nickel, lead, copper, tin, etc.). In one embodiment, the thermal conductive plate 58 is made of the same material as the lead frame 52, so as to reduce the material cost and management cost. The shape of the thermal conductive plate 58 is simple and it does not require to be specially prepared in advance. The high thermal conductive material refers to a material having a thermal conductivity coefficient higher than the package material 5A.

In the embodiments as shown in FIGS. 2, 3, and 4, the thermal conductive plate 58 does not directly contact the lead frame 52. The thermal conductive plate 58 is adhered to the chip die 54 through the thermal conductive adhesive layer 56, wherein the thermal conductive plate 58 does not have a complicated shape as in the prior art. The thermal conductive plate 58 is adhered to the chip die 54 simply by the thermal conductive adhesive layer 56, and as such, heat can dissipate from the chip die 54 to outside with good effect.

In the embodiments as shown in FIGS. 2 and 4, a part of the lead wires 55 above the chip die 54 are buried in the thermal conductive adhesive layer 56, that is, the thermal conductive adhesive layer 56 encapsulates the lead wire 55 thereinto. The welding spots of the lead wires 55 on the chip die 54 are located between the thermal conductive adhesive layer 56 and the chip die 54; such arrangement can increase the surface coverage of the thermal conductive adhesive layer 56 on the chip die 54. For example, in the package structure 70 as shown in FIG. 4, the coverage (surface area) of thermal conductive adhesive layer 56 can be larger than the area of the top surface of the chip die 54. Or in another embodiment, the welding spots of the lead wires 55 are located under the thermal conductive adhesive layer 56, wherein besides the contact surface between the top surface of the chip die 54 and the thermal conductive adhesive layer 56, the top surface of the chip die 54 substantially does not need extra area, that is, the size of the chip die 54 can be kept as small as possible.

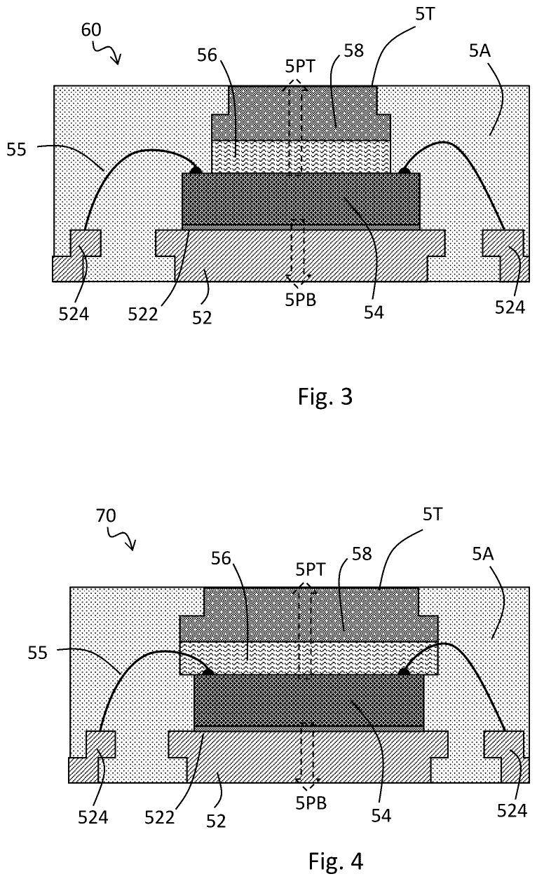

Please refer to FIG. 3; in one embodiment, the part of the lead wires 55 above the chip die 54 are located outside the thermal conductive adhesive layer 56. In this embodiment, the manufacturing method step of forming the thermal conductive adhesive layer 56 on the chip die 54 does not need to include a step of burying the lead wires 55 into the thermal conductive adhesive layer 56.

In the embodiments as shown in FIGS. 2, 3, and 4, the lead frame 52, the chip die 54, the thermal conductive adhesive layer 56, and the thermal conductive plate 58 are respectively disposed at different elevation levels. The manufacturing method of the package structures 50, 60, and 70 is performed layer-by-layer, which is straightforward and much easier than the prior art; there is no need to align the heat dissipation cover on the lead frame, nor is it required to design the shape of the heat dissipation cover according to the three-dimensional shape of the chip die.

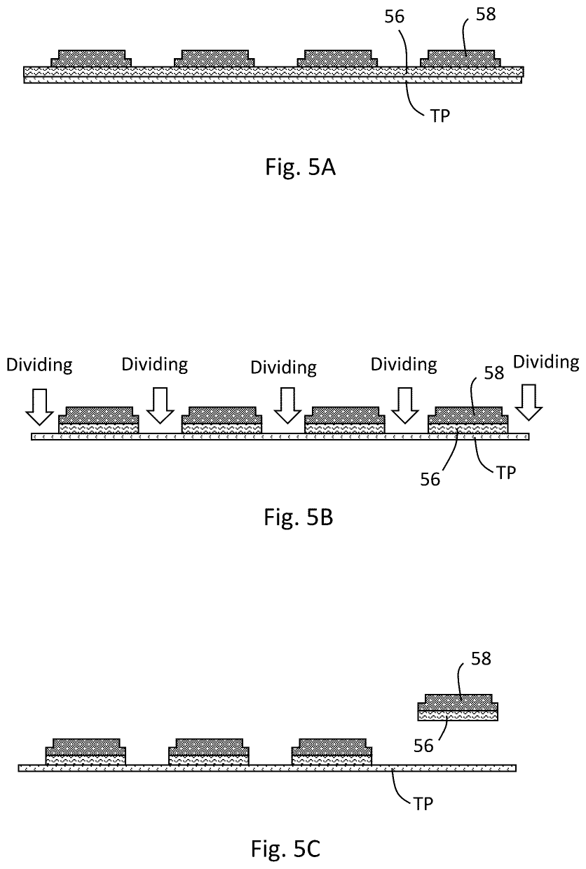

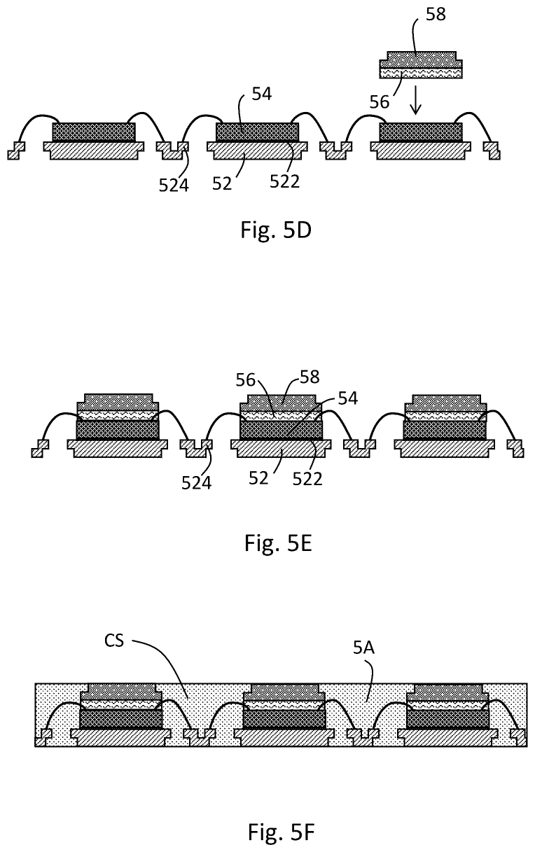

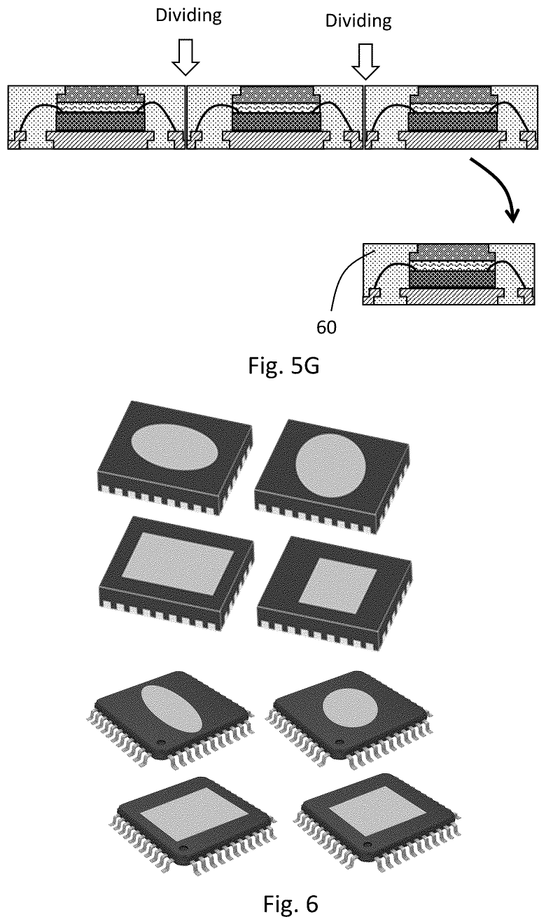

In one embodiment of the packaging method of the package structures 50, 60, and 70 (to be described in detail later), plural thermal conductive plates 58 are disposed on a tape TP via a thermal conductive adhesive layer 56 (FIG. 5A), and thereafter, each set of the thermal conductive plate 58 and the corresponding divided thermal conductive adhesive layer 56 is removed from the tape TP; next, each set is disposed on a corresponding chip die 54 (FIGS. 5C and 5D).

In some embodiments, the package structure of the present invention, can be applied to the following package types: quad flat no lead (QFN), quad flat package (QFP), ball grid array (BGA), land grid array (LGA), or dual flat no lead (DEN).

Note that the sizes, shapes and numbers of the lead frame 52, the chip die 54, the thermal conductive adhesive layer 56, and the thermal conductive plate 58 can be modified according to different implementation conditions, which are not limited to those shown in the drawings.

In one embodiment, in a top view perpendicular to the top surface 5T, an exposed portion of the thermal conductive plates 58 on the package structure 50, 60, or 70, includes a shape of square, rectangular, circle, oval, triangular, or polygonal (FIG. 6).

In one perspective, the present invention provides a packaging method, which includes steps of: providing a tape TP, which includes plural sets of thermal conductive adhesive layers 56 and thermal conductive plates 58 thereon, as shown in FIGS. 5A and 5B (wherein FIG. 5A shows a state before dividing the thermal conductive adhesive layer 56 on the tape TP, and FIG. 5B shows a state after dividing the thermal conductive adhesive layer 56 on the tape TP); removing each set of the divided thermal conductive adhesive layer 56 and the thermal conductive plate 58 from the tape TP (FIG. 5C); providing plural lead frames 52 connected to each other, each of the lead frames 52 including a die pad 522 and plural lead pads 524, wherein a chip die 54 is disposed on the die pad 522, and plural lead wires 55 are disposed between the chip die 54 and the lead pads 524 (FIG. 5D); disposing each set of the thermal conductive adhesive layer 56 and the thermal conductive plate 58 on a corresponding one of the chip dies 54 (FIGS. 5D and 5E); providing a package material 5A to encapsulate the lead frames 52, the chip dies 54, the thermal conductive adhesive layers 56, and the thermal conductive plates 58, to form a continuous pre-cutting package structure CS (FIG. 5F), wherein a top surface of each of the thermal conductive plates 58 is exposed on a top surface of the continuous pre-cutting package structure CS, and a bottom surface of the lead frames 62 is exposed on a bottom surface of the continuous pre-cutting package structure CS; and dividing the continuous pre-cutting package structure CS into plural package structures 60 (FIG. 5G). Each of the package structures 60 includes an upper thermal conduction path 5PT and a lower thermal conduction path 5PB (FIG. 3), wherein the upper thermal conduction path 5PT passing through the chip die 54, the thermal conductive adhesive layer 56, and the thermal conductive plate 58, and the lower thermal conduction path 5PB passing through the chip die 54 and the lead frame 52.

The tape TP is for carrying the thermal conductive adhesive layer 56 and the thermal conductive plate 58, and serves as a supporter when dividing the thermal conductive adhesive layer 56 thereon; the tape can be made of any material that can serve the above functions. The continuous pre-cutting package structure CS is a continuous object formed by encapsulating the lead frames 52, the chip dies 54, the thermal conductive adhesive layers 56, and the thermal conductive plates 58 in the package material 5A, and is later divided into independent package structures 60. As per the details of the package material, the lead frame 52, the chip die 54, the thermal conductive adhesive layer 56, the thermal conductive plate 58 of the package structure 60, please refer to the aforementioned embodiments.

The aforementioned method embodiment is described by taking the package structure 60 as an example; the same method can be used to manufacture the package structure 50 or 70, or other types of the package structures under the same spirit of the present invention. Further, the sizes, shapes and numbers of the manufactured package structures are not limited to what are shown in the drawings.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. For example, the number of the chip dies can be different from the disposition as shown in drawings; the components placed can be disposed in a different sequence; or, the shapes of the components are different from the drawings, etc. Those skilled in this art can readily conceive variations and modifications within the spirit of the present invention.

What is claimed is:

1. A package structure, comprising:
a lead frame, including a die pad and a plurality of lead pads around the die pad;
a chip die, disposed on the die pad, wherein the lead pads are electrically connected with the chip die via a plurality of lead wires, respectively;
a thermal conductive adhesive layer, disposed on the chip die at a same elevation level as a part of the lead wires above the chip die;
a thermal conductive plate, disposed on the thermal conductive adhesive layer; and
a packaging material, encapsulating the lead frame, the chip die, the thermal conductive adhesive layer, and the thermal conductive plate, wherein the thermal conductive plate is exposed on a top surface of the package material, and the lead frame is exposed on a bottom surface of the package material;
wherein the package structure includes an upper thermal conduction path and a lower thermal conduction path, the upper thermal conduction path passing through the chip die, the thermal conductive adhesive layer, and the thermal conductive plate, and the lower thermal path passing through the chip die and the lead frame.

2. The package structure according to claim 1, wherein the thermal conductive plate does not contact the lead frame.

3. The package structure according to claim 1, wherein a part of the lead wires above the chip die are buried in the thermal conductive adhesive layer; or, a part of the lead wires above the chip die are disposed outside the thermal conductive adhesive layer.

4. The package structure according to claim 1, wherein the lead frame, the chip die, the thermal conductive adhesive layer, and the thermal conductive plate are respectively disposed at different elevation levels.

5. The package structure according to claim 1, wherein in a manufacturing process of the package structure, the thermal conductive plates are disposed on a tape by the thermal conductive adhesive layer, whereafter each set of the thermal conductive plate and the thermal conductive adhesive layer is removed from the tape, to be disposed on the corresponding chip die.

6. The package structure according to claim 1, wherein the package structure is applied to a package of quad flat no lead (QFN), quad flat package (QFP), ball grid array (BGA), land grid array (LGA), or dual flat no lead (DEN).

7. The package structure according to claim 1, wherein an exposed portion of the thermal conductive plate on the package material includes a shape of square, rectangular, circle, oval, triangular, or polygonal.

8. A packaging method, comprising:
providing a tape, which includes plural sets of thermal conductive adhesive layers and thermal conductive plates thereon;
removing each set of the thermal conductive adhesive layer and thermal conductive plate from the tape;
providing a plurality of lead frames connected to each other, each of the lead frames including a die pad and a plurality of lead pads, wherein a chip die is disposed on the die pad, and a plurality of lead wires are disposed between the chip die and the lead pads;
disposing each set of the thermal conductive adhesive layer and the thermal conductive plate on a corresponding one of the chip dies;
providing a package material to encapsulate the lead frames, the chip dies, the thermal conductive adhesive layers, and the thermal conductive plates, to form a continuous pre-cutting package structure, wherein a top surface of the thermal conductive plate is exposed on a top surface of the continuous pre-cutting package structure, and a bottom surface of the lead frames is exposed on a bottom surface of the continuous pre-cutting package structure; and
dividing the continuous package structure into a plurality of package structures;
wherein each of the package structures includes an upper thermal conduction path and a lower thermal conduction path, the upper thermal conduction path passing through the chip die, the thermal conductive adhesive layer, and the thermal conductive plate, the lower thermal path passing through the chip die and the lead frame.

9. The packaging method according to claim 8, wherein a part of the lead wires above the chip die are buried in the thermal conductive adhesive layer; or, a part of the lead wires above the chip die are disposed outside the thermal conductive adhesive layer.

10. The packaging method according to claim 8, wherein the lead frame, the chip die, the thermal conductive adhesive layer, and the thermal conductive plate are respectively disposed at different elevation levels in the package structure.

11. The packaging method according to claim 8, wherein the thermal conductive plate does not contact the lead frame.
